(19) United States
(12) Patent Application Publication
(10) Pub. No.: US 2024/0099110 A1
(43) Pub. Date: Mar. 21, 2024

(54) MANUFACTURING DEVICE OF DISPLAY DEVICE AND MANUFACTURING METHOD OF DISPLAY DEVICE

(71) Applicant: Japan Display Inc., Tokyo (JP)

(72) Inventors: Hirofumi MIZUKOSHI, Tokyo (JP); Takanobu TAKENAKA, Tokyo (JP); Masaru TAKAYAMA, Tokyo (JP); Kaichi FUKUDA, Tokyo (JP)

(73) Assignee: Japan Display Inc., Tokyo (JP)

(21) Appl. No.: 18/470,437

(22) Filed: Sep. 20, 2023

(30) Foreign Application Priority Data
Sep. 21, 2022 (JP) 2022-150502

(51) Int. Cl. H10K 59/80; H10K 71/20

(52) U.S. Cl. CPC H10K 59/879; H10K 59/871; H10K 71/233

(57) ABSTRACT

According to one embodiment, a manufacturing method of a display device includes preparing a processing substrate by forming a lower electrode, a rib and a partition, forming an organic layer on the lower electrode, forming an upper electrode on the organic layer, forming a first transparent layer on the upper electrode by depositing a first organic material, forming a second transparent layer on the first transparent layer by depositing a second organic material, and depositing the second organic material on each of a plurality of crystal oscillators included in a film thickness measurement device by emitting the second organic material from first and second nozzles of an evaporation source before forming the second transparent layer.

### CROSS-REFERENCE TO RELATED APPLICATIONS

This application is based upon and claims the benefit of priority from Japanese Patent Application No. 2022-150502, filed Sep. 21, 2022, the entire contents of which are incorporated herein by reference.

### FIELD

Embodiments described herein relate generally to a manufacturing device of a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In a manufacturing device for forming such a display element, the prevention of the reduction in the production efficiency is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram showing an example of the configuration of display elements 201 to 203.

FIG. 5 is a flow diagram for explaining an example of the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining a configuration example of a manufacturing device 100.

FIG. 14 is a perspective view schematically showing the main part of an evaporation portion 300.

FIG. 15 is a top view schematically showing the main part of the evaporation portion 300.

FIG. 16 is a front view of a cover 322 and a holder 323.

FIG. 17 is a flowchart for explaining a pre-deposition process.

FIG. 18 is a flowchart for explaining the deposition process of a material relative to a processing substrate SUB.

### DETAILED DESCRIPTION

Embodiments described herein aim to provide a manufacturing device of a display device and a manufacturing method of a display device such that the reduction in the production efficiency can be prevented.

In general, according to one embodiment, a manufacturing method of a display device comprises preparing a processing substrate by forming a lower electrode above a substrate, forming a rib comprising an aperture which overlaps the lower electrode, and forming a partition including a lower portion located on the rib and an upper portion located on the lower portion and protruding from a side surface of the lower portion, forming an organic layer on the lower electrode in the aperture, forming an upper electrode on the organic layer, forming a first transparent layer on the upper electrode by depositing a first organic material on the processing substrate in which the upper electrode is formed, forming a second transparent layer on the first transparent layer by depositing a second organic material having a refractive index lower than a refractive index of the first organic material on the processing substrate in which the first transparent layer is formed, and depositing the second organic material on each of a plurality of crystal oscillators included in a film thickness measurement device facing the second nozzle by emitting the second organic material from first and second nozzles of an evaporation source before forming the second transparent layer.

According to another embodiment, a manufacturing device of a display device comprises a first evaporation portion which forms, while conveying a processing substrate comprising a lower electrode located above a substrate, a rib comprising an aperture overlapping the lower electrode, and a partition including a lower portion located on the rib and an upper portion located on the lower portion and protruding from a side surface of the lower portion, an organic layer on the lower electrode in the aperture, a second evaporation portion which forms an upper electrode on the organic layer, a third evaporation portion which forms a first transparent layer by depositing a first organic material on the upper electrode, and a fourth evaporation portion which forms a second transparent layer by depositing a second organic material having a refractive index lower than a refractive index of the first organic material on the first transparent layer. The fourth evaporation portion comprises an evaporation source comprising first and second nozzles which emit the second organic material, and a film thickness measurement device including a plurality of crystal oscillators. The first nozzle faces a conveyance path of the processing substrate in which the first transparent layer is formed. The second nozzle faces the film thickness measurement device. The fourth evaporation portion is configured to emit the second organic material from the first nozzle and the second nozzle before the second transparent layer is formed, deposit the second organic material on each of the crystal oscillators, and convey the processing substrate along the conveyance path after the second organic material is deposited on all of the crystal oscillators.

The embodiments can provide a manufacturing device of a display device and a manufacturing method of a display device such that the reduction in the production efficiency can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. When various elements are viewed parallel to the third direction Z, the appearance is defined as a plan view. When terms indicating the positional relationships of two or more structural elements, such as “on”, “above”, “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

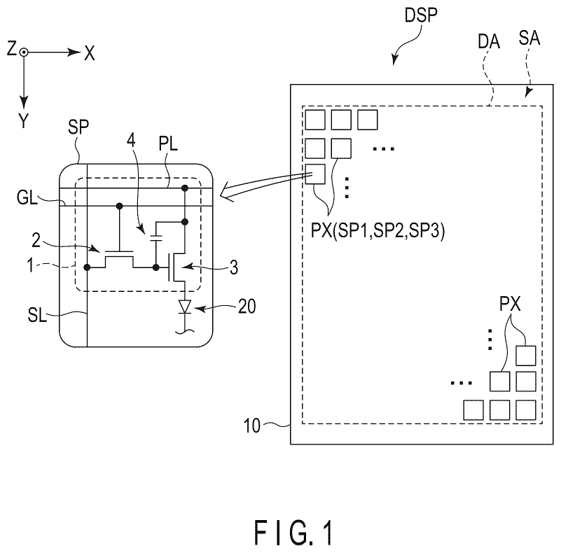

FIG. 1 is a diagram showing a configuration example of a display device DSP.

The display device DSP comprises a display area DA which displays an image and a surrounding area SA around the display area DA on an insulating substrate 10. The substrate 10 may be glass or a resinous film having flexibility.

In the present embodiment, the substrate 10 is rectangular in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Although not described in detail, a terminal for connecting an IC chip and a flexible printed circuit substrate is provided in the surrounding area SA.

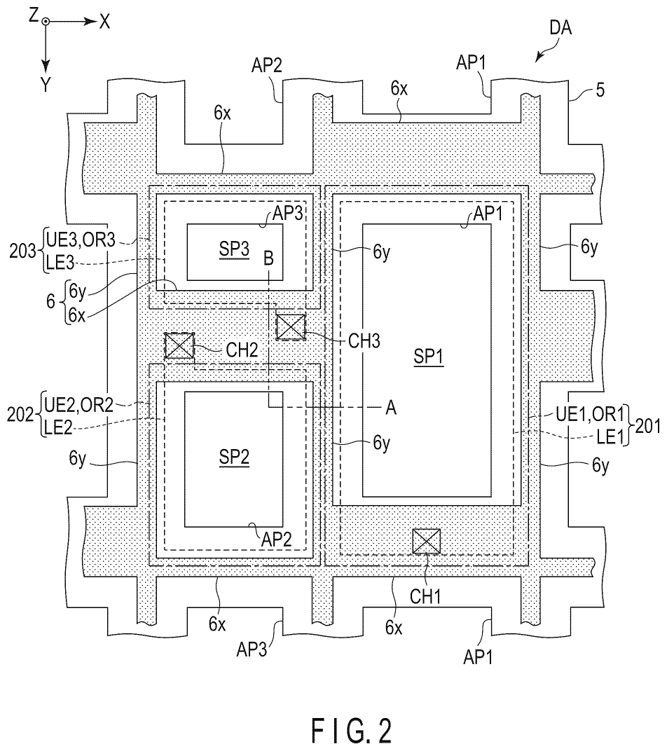

FIG. 2 is a diagram showing an example of the layout of subpixels SP1, SP2 and SP3.

In the example of FIG. 2, subpixels SP2 and SP3 are arranged in the second direction Y. Further, each of subpixels SP2 and SP3 is adjacent to subpixel SP1 in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 in plan view. The partition 6 comprises a plurality of first partitions 6x extending in the first direction X and a plurality of second partitions 6y extending in the second direction Y. The first partitions 6x are provided between the apertures AP2 and AP3 which are adjacent to each other in the second direction Y and between two apertures AP1 which are adjacent to each other in the second direction Y. Each second partition 6y is provided between the apertures AP1 and AP2 which are adjacent to each other in the first direction X and between the apertures AP1 and AP3 which are adjacent to each other in the first direction X.

In the example of FIG. 2, the first partitions 6x and the second partitions 6y are connected to each other. Thus, the partition 6 is formed into a grating shape surrounding the apertures AP1, AP2 and AP3 as a whole. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

Subpixel SP1 comprises a lower electrode LE1, an upper electrode UE1 and an organic layer OR1 overlapping the aperture AP1. Subpixel SP2 comprises a lower electrode LE2, an upper electrode UE2 and an organic layer OR2 overlapping the aperture AP2. Subpixel SP3 comprises a lower electrode LE3, an upper electrode UE3 and an organic layer OR3 overlapping the aperture AP3.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. The peripheral portion of each of the lower electrodes LE1, LE2 and LE3 overlaps the rib 5. It should be noted that the outer shape of each of the lower electrodes, organic layers and upper electrodes shown in the figure does not necessarily reflect the accurate shape.

The lower electrode LE1, the upper electrode UE1 and the organic layer OR1 constitute the display element 201 of subpixel SP1. The lower electrode LE2, the upper electrode UE2 and the organic layer OR2 constitute the display element 202 of subpixel SP2. The lower electrode LE3, the upper electrode UE3 and the organic layer OR3 constitute the display element 203 of subpixel SP3.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

For example, the display element 201 of subpixel SP1 is configured to emit light in a blue wavelength range. The display element 202 of subpixel SP2 is configured to emit light in a green wavelength range. The display element 203 of subpixel SP3 is configured to emit light in a red wavelength range.

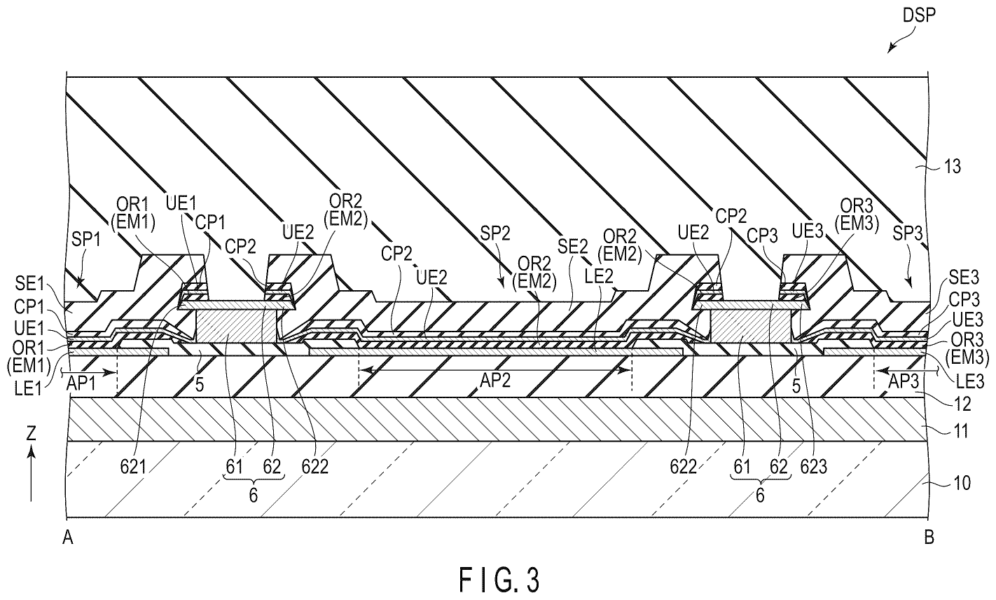

FIG. 3 is a schematic cross-sectional view of the display device DSP along the A-B line of FIG. 2.

A circuit layer 11 is provided on the substrate 10 described above. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 functions as a planarization film which planarizes the irregularities formed by the circuit layer 11.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5. In other words, the end portions of the lower electrodes LE1, LE2 and LE3 are provided between the insulating layer 12 and the rib 5. Of the lower electrodes LE1, LE2 and LE3, between the lower electrodes which are adjacent to each other, the insulating layer 12 is covered with the rib 5.

The partition 6 includes a lower portion (stem) 61 provided on the rib 5 and an upper portion (shade) 62 provided on the lower portion 61. The lower portion 61 of the partition 6 shown on the left side of the figure is located between the aperture AP1 and the aperture AP2. The lower portion 61 of the partition 6 shown on the right side of the figure is located between the aperture AP2 and the aperture AP3. The upper portion 62 has a width greater than that of the lower portion 61. By this configuration, the both end portions of the upper portion 62 protrude relative to the side surfaces of the lower portion 61. This shape of the partition 6 may be called an overhang shape. Of the upper portion 62, a portion which protrudes to the aperture AP1 relative to the lower portion 61 is referred to as a protrusion 621. A portion which protrudes to the aperture AP2 relative to the lower portion 61 is referred to as a protrusion 622. A portion which protrudes to the aperture AP3 relative to the lower portion 61 is referred to as a protrusion 623.

The organic layer OR1 is in contact with the lower electrode LE1 through the aperture AP1, covers the lower electrode LE1 and overlaps part of the rib 5. The upper electrode UE1 faces the lower electrode LE1 and is provided on the organic layer OR1. Further, the upper electrode UE1 is in contact with a side surface of the lower portion 61. The organic layer OR1 and the upper electrode UE1 are located on the lower side relative to the upper portion 62.

The organic layer OR2 is in contact with the lower electrode LE2 through the aperture AP2, covers the lower electrode LE2 and overlaps part of the rib 5. The upper electrode UE2 faces the lower electrode LE2 and is provided on the organic layer OR2. Further, the upper electrode UE2 is in contact with a side surface of the lower portion 61. The organic layer OR2 and the upper electrode UE2 are located on the lower side relative to the upper portion 62.

The organic layer OR3 is in contact with the lower electrode LE3 through the aperture AP3, covers the lower electrode LE3 and overlaps part of the rib 5. The upper electrode UE3 faces the lower electrode LE3 and is provided on the organic layer OR3. Further, the upper electrode UE3 is in contact with a side surface of the lower portion 61. The organic layer OR3 and the upper electrode UE3 are located on the lower side relative to the upper portion 62.

Subpixels SP1, SP2 and SP3 further include cap layers (optical adjustment layers) CP1, CP2 and CP3 for adjusting the optical property of the light emitted from the light emitting layers of the organic layers OR1, OR2 and OR3.

The cap layer CP1 is located in the aperture AP1, is located on the lower side relative to the upper portion 62 and is provided on the upper electrode UE1. The cap layer CP2 is located in the aperture AP2, is located on the lower side relative to the upper portion 62 and is provided on the upper electrode UE2. The cap layer CP3 is located in the aperture AP3, is located on the lower side relative to the upper portion 62 and is provided on the upper electrode UE3.

Sealing layers SE1, SE2 and SE3 are provided in subpixels SP1, SP2 and SP3, respectively.

The sealing layer SE1 is in contact with the cap layer CP1 and the lower and upper portions 61 and 62 of the partition 6 and continuously covers the members of subpixel SP1. The sealing layer SE2 is in contact with the cap layer CP2 and the lower and upper portions 61 and 62 of the partition 6 and continuously covers the members of subpixel SP2. The sealing layer SE3 is in contact with the cap layer CP3 and the lower and upper portions 61 and 62 of the partition 6 and continuously covers the members of subpixel SP3.

The sealing layers SE1, SE2 and SE3 are covered with a protective layer 13.

In the example shown in the figure, part of the organic layer OR1, part of the upper electrode UE1 and part of the cap layer CP1 are located between the partition 6 and the sealing layer SE1, are provided on the upper portion 62 and are spaced apart from the portions located on the lower side relative to the upper portion 62.

Part of the organic layer OR2, part of the upper electrode UE2 and part of the cap layer CP2 are located between the partition 6 and the sealing layer SE2, are provided on the upper portion 62 and are spaced apart from the portions located on the lower side relative to the upper portion 62.

Part of the organic layer OR3, part of the upper electrode UE3 and part of the cap layer CP3 are located between the partition 6 and the sealing layer SE3, are provided on the upper portion 62 and are spaced apart from the portions located on the lower side relative to the upper portion 62.

The insulating layer 12 is an organic insulating layer. The rib 5 and the sealing layers SE1, SE2 and SE3 are inorganic insulating layers.

The rib 5 is formed of silicon nitride (SiNx) as an example of inorganic insulating materials. It should be noted that the rib 5 may be formed of, as another inorganic insulating material, a single-layer body of one of silicon oxide (SiOx), silicon oxynitride (SiON) and aluminum oxide (Al₂O₃). The rib 5 may be formed of a stacked layer body of a combination consisting of at least two of a silicon nitride layer, a silicon oxide layer, a silicon oxynitride layer and an aluminum oxide layer.

The sealing layers SE1, SE2 and SE3 are formed of, for example, the same inorganic insulating material.

Each of the sealing layers SE1, SE2 and SE3 is formed of silicon nitride (SiNx) as an example of inorganic insulating materials. It should be noted that each of the sealing layers SE1, SE2 and SE3 may be formed of, as another inorganic insulating material, a single-layer body of one of silicon oxide (SiOx), silicon oxynitride (SiON) and aluminum oxide (Al₂O₃). Each of the sealing layers SE1, SE2 and SE3 may be formed of a stacked layer body of a combination consisting of at least two of a silicon nitride layer, a silicon oxide layer, a silicon oxynitride layer and an aluminum oxide layer. Thus, the sealing layers SE1, SE2 and SE3 could be formed of the same material as the rib 5.

The lower portion 61 of the partition 6 is formed of a conductive material and is electrically connected to the upper electrodes UE1, UE2 and UE3. Both the lower portion 61 and the upper portion 62 of the partition 6 may be formed of a conductive material.

The thickness of the rib 5 is sufficiently less than that of each of the partition 6 and the insulating layer 12. For example, the thickness of the rib 5 is greater than or equal to 200 nm but less than or equal to 400 nm.

The thickness of the lower portion 61 of the partition 6 (the thickness from the upper surface of the rib 5 to the lower surface of the upper portion 62) is greater than that of the rib 5.

The thickness of the sealing layer SE1, the thickness of the sealing layer SE2 and the thickness of the sealing layer SE3 are substantially equal to each other and are, for example, approximately 1 μm.

Each of the lower electrodes LE1, LE2 and LE3 may be formed of a transparent conductive material such as ITO or may comprise a multilayer structure of a metal material such as silver (Ag) and a transparent conductive material. Each of the upper electrodes UE1, UE2 and UE3 is formed of, for example, a metal material such as an alloy of magnesium and silver (MgAg). Each of the upper electrodes UE1, UE2 and UE3 may be formed of a transparent conductive material such as ITO.

Each of the organic layers OR1, OR2 and OR3 includes a plurality of functional layers such as a hole injection layer, a hole transport layer, an electron blocking layer, a hole blocking layer, an electron transport layer and an electron injection layer. The organic layer OR1 includes a light emitting layer EM1. The organic layer OR2 includes a light emitting layer EM2. The light emitting layer EM2 is formed of a material different from that of the light emitting layer EM1. The organic layer OR3 includes a light emitting layer EM3. The light emitting layer EM3 is formed of a material different from the materials of the light emitting layers EM1 and EM2.

The material of the light emitting layer EM1, the material of the light emitting layer EM2 and the material of the light emitting layer EM3 are materials which emit light in different wavelength ranges.

For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the cap layers CP1, CP2 and CP3 is formed of, for example, a multilayer body of transparent thin films. As the thin films, the multilayer body includes a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. At least one of the cap layers CP1, CP2 and CP3 may be omitted.

The protective layer 13 is formed of a multilayer body of transparent thin films. For example, as the thin films, the multilayer body includes a thin film formed of an inorganic material and a thin film formed of an organic material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer EM1 of the organic layer OR1 emits light in a blue wavelength range. When a potential difference is formed between the lower electrode LE2 and the upper electrode UE2, the light emitting layer EM2 of the organic layer OR2 emits light in a green wavelength range. When a potential difference is formed between the lower electrode LE3 and the upper electrode UE3, the light emitting layer EM3 of the organic layer OR3 emits light in a red wavelength range.

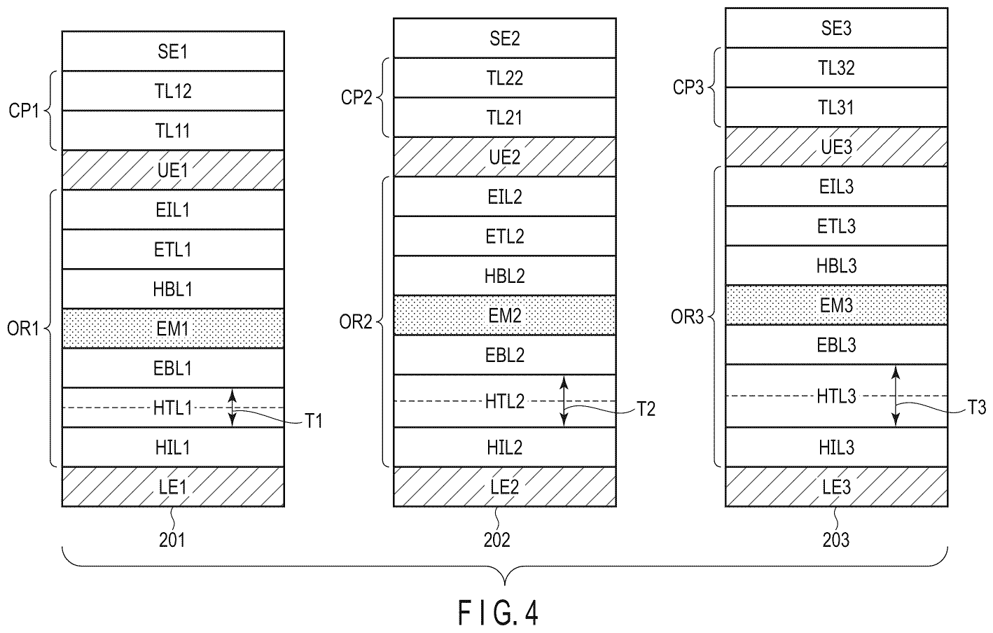

FIG. 4 is a diagram showing an example of the configuration of the display elements 201 to 203.

Here, this specification explains an example in which each lower electrode corresponds to an anode and each upper electrode corresponds to a cathode.

The display element 201 includes the organic layer OR1 between the lower electrode LE1 and the upper electrode UE1.

In the organic layer OR1, a hole injection layer HIL1, a hole transport layer HTL1, an electron blocking layer EBL1, the light emitting layer EM1, a hole blocking layer HBL1, an electron transport layer ETL1 and an electron injection layer EIL1 are stacked in this order.

The cap layer CP1 includes a first transparent layer TL11 and a second transparent layer TL12. The first transparent layer TL11 is provided on the upper electrode UE1. The second transparent layer TL12 is provided on the first transparent layer TL11. The sealing layer SE1 is provided on the second transparent layer TL12.

The display element 202 includes the organic layer OR2 between the lower electrode LE2 and the upper electrode UE2.

In the organic layer OR2, a hole injection layer HIL2, a hole transport layer HTL2, an electron blocking layer EBL2, the light emitting layer EM2, a hole blocking layer HBL2, an electron transport layer ETL2 and an electron injection layer EIL2 are stacked in this order. For example, thickness T2 of the hole transport layer HTL2 is greater than thickness T1 of the hole transport layer HTL1.

The cap layer CP2 includes a first transparent layer TL21 and a second transparent layer TL22. The first transparent layer TL21 is provided on the upper electrode UE2. The second transparent layer TL22 is provided on the first transparent layer TL21. The sealing layer SE2 is provided on the second transparent layer TL22.

The display element 203 includes the organic layer OR3 between the lower electrode LE3 and the upper electrode UE3.

In the organic layer OR3, a hole injection layer HIL3, a hole transport layer HTL3, an electron blocking layer EBL3, the light emitting layer EM3, a hole blocking layer HBL3, an electron transport layer ETL3 and an electron injection layer EIL3 are stacked in this order. For example, thickness T3 of the hole transport layer HTL3 is greater than thickness T2 of the hole transport layer HTL2.

The cap layer CP3 includes a first transparent layer TL31 and a second transparent layer TL32. The first transparent layer TL31 is provided on the upper electrode UE3. The second transparent layer TL32 is provided on the first transparent layer TL31. The sealing layer SE3 is provided on the second transparent layer TL32.

The first transparent layers TL11, TL21 and TL31 are transparent organic layers each formed of a first organic material, and are high refractive layers having refractive indices greater than those of the upper electrodes UE1, UE2 and UE3. For example, the refractive index of each of the first transparent layers TL11, TL21 and TL31 is greater than or equal to 1.7 but less than or equal to 2.0.

The second transparent layers TL12, TL22 and TL32 are transparent organic layers each formed of a second organic material, and are low refractive layers having refractive indices less than those of the first transparent layers TL11, TL21 and TL31. For example, the refractive index of each of the second transparent layers TL12, TL22 and TL32 is greater than or equal to 1.3 but less than or equal to 1.6.

The refractive indices of the sealing layers SE1, SE2 and SE3 which are in contact with the second transparent layers TL12, TL22 and TL32 are greater than those of the second transparent layers TL12, TL22 and TL32. For example, the refractive index of each of the sealing layers SE1, SE2 and SE3 is greater than or equal to 1.7 but less than or equal to 2.0.

As the second organic material for forming the second transparent layers TL12, TL22 and TL32, fluorine resin in which the main chain consists of carbon and which contains fluorine in a substituent is desirable. For example, each of the second transparent layers TL12, TL22 and TL32 can be formed of at least one second organic material from polytetrafluoroethylene (PTFE), polyvinylidene fluoride (PVDF) and 2-(perfluorohexyl)ethyl acrylate. The refractive index of polytetrafluoroethylene is 1.35. The refractive index of polyvinylidene fluoride is 1.42. The refractive index of 2-(perfluorohexyl)ethyl acrylate is 1.35.

The second transparent layers TL12, TL22 and TL32 to which these second organic materials are applied can be formed by a vapor deposition method. The thickness of each of these second transparent layers TL12, TL22 and TL32 is, for example, 20 nm to 500 nm.

The first transparent layers TL11, TL21 and TL31 are spaced apart from each other and are individually formed. Thus, all of the first transparent layers TL11, TL21 and TL31 may be formed of the same material, or one of the first transparent layers TL11, TL21 and TL31 may be formed of a material different from that of the other two transparent layers, or all of the first transparent layers TL11, TL21 and TL31 may be formed of materials different from each other.

The second transparent layers TL12, TL22 and TL32 are spaced apart from each other and are individually formed. Thus, all of the second transparent layers TL12, TL22 and TL32 may be formed of the same material, or one of the second transparent layers TL12, TL22 and TL32 may be formed of a material different from that of the other two transparent layers, or all of the second transparent layers TL12, TL22 and TL32 may be formed of materials different from each other.

All of the thicknesses of the first transparent layers TL11, TL21 and TL31 may be the same as each other, or may be different from each other.

All of the thicknesses of the second transparent layers TL12, TL22 and TL32 may be the same as each other, or may be different from each other.

For example, all of the thicknesses of the second transparent layers TL12, TL22 and TL32 are the same as each other. The thickness of the first transparent layer TL11 in the display element 201 for blue is less than that of the first transparent layer TL31 in the display element 203 for red.

In the display element 201, the thickness of the second transparent layer TL12 is greater than that of the first transparent layer TL11. In the display element 203, the thickness of the first transparent layer TL31 is less than that of the second transparent layer TL32.

All of the layer structures of the cap layers CP1 to CP3 may be the same as each other, or the layer structure of one of the cap layers CP1 to CP3 may be different from that of the other two cap layers, or all of the layer structures of the cap layers CP1 to CP3 may be different from each other.

Each of the cap layers CP1, CP2 and CP3 may be a stacked layer body consisting of three or more layers.

It should be noted that each of the organic layers OR1, OR2 and OR3 may include, in addition to the functional layers described above, other functional layers such as a carrier generation layer as needed, or at least one of the above functional layers may be omitted.

For example, each of the hole transport layers HTL1, HTL2 and HTL3 is a multilayer body consisting of two thin films formed of materials different from each other as shown by dotted lines in the figure. However, each of the hole transport layers HTL1, HTL2 and HLT3 may be a single-layer body formed of a single material.

Each of the display elements 201 to 203 is not limited to the single configuration shown in the figure and may comprise a tandem configuration.

Now, this specification explains an example of the manufacturing method of the display device DSP.

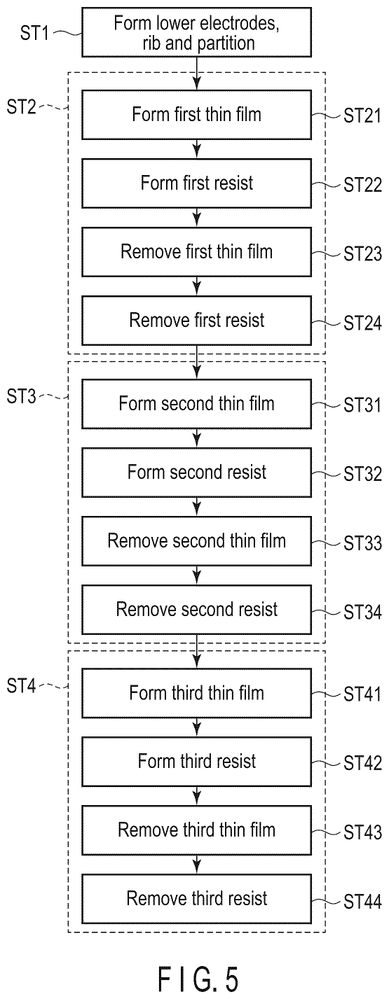

FIG. 5 is a flow diagram for explaining an example of the manufacturing method of the display device DSP.

The manufacturing method shown here roughly includes the process of preparing a processing substrate SUB comprising subpixels SP1, SP2 and SP3 (step ST1), the process of forming the display element 201 of subpixel SP1 (step ST2), the process of forming the display element 202 of subpixel SP2 (step ST3) and the process of forming the display element 203 of subpixel SP3 (step ST4).

In step ST1, first, the processing substrate SUB is prepared by forming the lower electrode LE1 of subpixel SP1, the lower electrode LE2 of subpixel SP2, the lower electrode LE3 of subpixel SP3, the rib 5 and the partition 6 on the substrate 10. As shown in FIG. 3, the circuit layer 11 and the insulating layer 12 are also formed between the substrate 10 and the lower electrodes LE1, LE2 and LE3.

In step ST2, first, a first thin film 31 including the light emitting layer EM1 is formed over subpixel SP1, subpixel SP2 and subpixel SP3 (step ST21). The first thin film 31 is a stacked layer body of the organic layer OR1, upper electrode UE1, cap layer CP1 and sealing layer SE1 shown in FIG. 3. Subsequently, a first resist 41 patterned into a predetermined shape is formed on the first thin film 31 (step ST22). Subsequently, part of the first thin film 31 is removed by etching using the first resist 41 as a mask (step ST23). At this time, for example, the first thin film 31 provided in subpixel SP2 and subpixel SP3 is removed. Subsequently, the first resist 41 is removed (step ST24). In this manner, subpixel SP1 is formed. Subpixel SP1 comprises the display element 201 comprising the first thin film 31 having a predetermined shape.

In step ST3, first, a second thin film 32 including the light emitting layer EM2 is formed over subpixel SP1, subpixel SP2 and subpixel SP3 (step ST31). The second thin film 32 is a stacked layer body of the organic layer OR2, upper electrode UE2, cap layer CP2 and sealing layer SE2 shown in FIG. 3. Subsequently, a second resist 42 patterned into a predetermined shape is formed on the second thin film 32 (step ST32). Subsequently, part of the second thin film 32 is removed by etching using the second resist 42 as a mask (step ST33). At this time, for example, the second thin film 32 provided in subpixel SP1 and subpixel SP3 is removed. Subsequently, the second resist 42 is removed (step ST34). In this manner, subpixel SP2 is formed. Subpixel SP2 comprises the display element 202 comprising the second thin film 32 having a predetermined shape.

In step ST4, first, a third thin film 33 including the light emitting layer EM3 is formed over subpixel SP1, subpixel SP2 and subpixel SP3 (step ST41). The third thin film 33 is a stacked layer body of the organic layer OR3, upper electrode UE3, cap layer CP3 and sealing layer SE3 shown in FIG. 3. Subsequently, a third resist 43 patterned into a predetermined shape is formed on the third thin film 33 (step ST42). Subsequently, part of the third thin film 33 is removed by etching using the third resist 43 as a mask (step ST43). At this time, for example, the third thin film 33 provided in subpixel SP1 and subpixel SP2 is removed. Subsequently, the third resist 43 is removed (step ST44). In this manner, subpixel SP3 is formed. Subpixel SP3 comprises the display element 203 comprising the third thin film 33 having a predetermined shape.

It should be noted that the detailed illustrations of the second thin film 32, the second resist 42, the third thin film 33 and the third resist 43 are omitted.

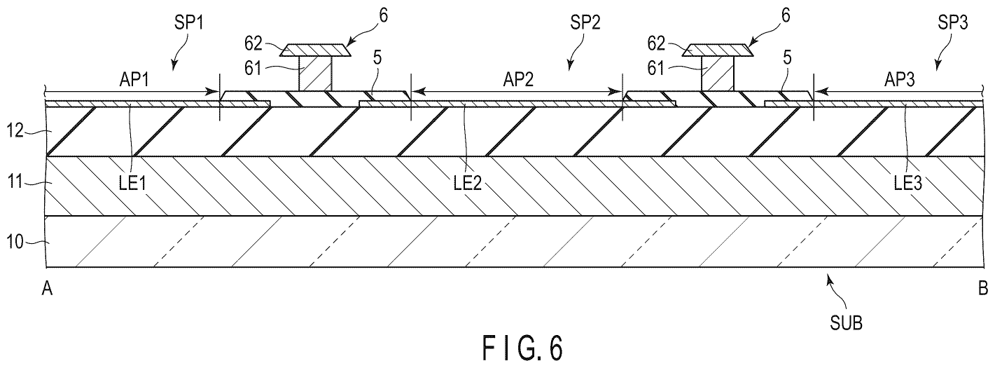

Now, this specification explains step ST1 and step ST2 with reference to FIG. 6 to FIG. 12. The section shown in each of FIG. 6 to FIG. 12 corresponds to, for example, the section taken along the A-B line of FIG. 2.

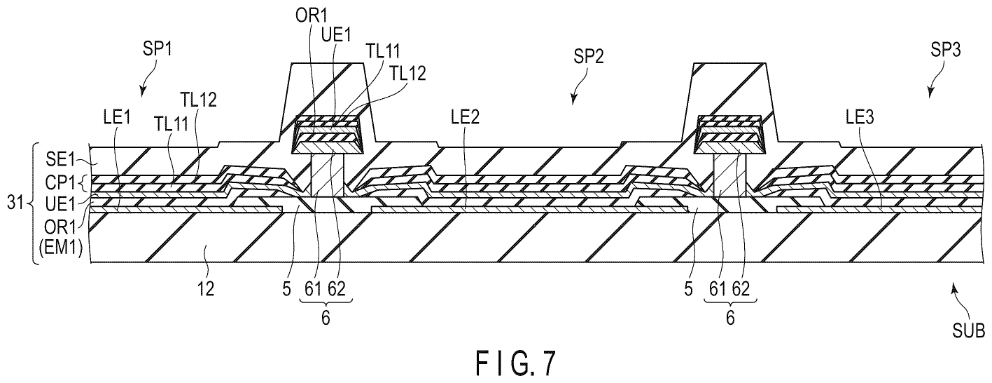

First, in step ST1, as shown in FIG. 6, the processing substrate SUB is prepared. The process of preparing the processing substrate SUB includes the process of forming the circuit layer 11 on the substrate 10, the process of forming the insulating layer 12 on the circuit layer 11, the process of forming the lower electrode LE1 of subpixel SP1, the lower electrode LE2 of subpixel SP2 and the lower electrode LE3 of subpixel SP3 on the insulating layer 12, the process of forming the rib 5 comprising the apertures AP1, AP2 and AP3 overlapping the lower electrodes LE1, LE2 and LE3, respectively, and the process of forming the partition 6 including the lower portion 61 provided on the rib 5 and the upper portion 62 provided on the lower portion 61 and protruding from the side surfaces of the lower portion 61. The rib 5 is formed of, for example, silicon nitride. Of the partition 6, at least the lower portion 61 is formed of a conductive material. In each of FIG. 7 to FIG. 12, the illustrations of the substrate 10 and the circuit layer 11 lower than the insulating layer 12 are omitted.

Subsequently, in step ST21, as shown FIG. 7, the first thin film 31 is formed over subpixel SP1, subpixel SP2 and subpixel SP3. The process of forming the first thin film 31 includes, on the processing substrate SUB, the process of forming the organic layer OR1 including the light emitting layer EM1, the process of forming the upper electrode UE1 on the organic layer OR1, the process of forming the first transparent layer TL11 of the cap layer CP1 on the upper electrode UE1, the process of forming the second transparent layer TL12 of the cap layer CP1 on the first transparent layer TL11 and the process of forming the sealing layer SE1 on the second transparent layer TL12. Thus, in the example shown in the figure, the first thin film 31 includes the organic layer OR1, the upper electrode UE1, the cap layer CP1 and the sealing layer SE1.

The organic layer OR1 is formed on each of the lower electrode LE1, the lower electrode LE2 and the lower electrode LE3 and is also formed on each partition 6. Of the organic layer OR1, the portion formed on each upper portion 62 is spaced apart from the portion formed on each of the lower electrodes LE1, LE2 and LE3. The light emitting layer EM1 and various functional layers of the organic layer OR1 are formed by a vapor deposition method.

The upper electrode UE1 is formed on the organic layer OR1 immediately above each of the lower electrodes LE1, LE2 and LE3, covers the rib 5 and is in contact with the lower portion 61 of each partition 6. The upper electrode UE1 is also formed on the organic layer OR1 immediately above each upper portion 62. Of the upper electrode UE1, the portion which is formed immediately above each upper portion 62 is spaced apart from the portion which is formed immediately above each of the lower electrodes LE1, LE2 and LE3. The upper electrode UE1 is formed of, for example, an alloy of magnesium and silver by a vapor deposition method.

The first transparent layer TL11 of the cap layer CP1 is formed on the upper electrode UE1 immediately above each of the lower electrodes LE1, LE2 and LE3, and is also formed on the upper electrode UE1 immediately above each upper portion 62. Of the first transparent layer TL11, the portion which is formed immediately above each upper portion 62 is spaced apart from the portion which is formed immediately above each of the lower electrodes LE1, LE2 and LE3. The first transparent layer TL11 is formed of the first organic material by a vapor deposition method.

The second transparent layer TL12 of the cap layer CP1 is formed on the first transparent layer TL11 immediately above each of the lower electrodes LE1, LE2 and LE3, and is also formed on the first transparent layer TL11 immediately above each upper portion 62. Of the second transparent layer TL12, the portion which is formed immediately above each upper portion 62 is spaced apart from the portion which is formed immediately above each of the lower electrodes LE1, LE2 and LE3. The second transparent layer TL12 is formed of the second organic material described above by a vapor deposition method. The second organic material is a material different from the first organic material. The refractive index of the second organic material is lower than that of the first organic material.

The sealing layer SE1 is formed so as to cover the second transparent layer TL12 and the partition 6. In other words, the sealing layer SE1 is formed on the second transparent layer TL12 immediately above each of the lower electrodes LE1, LE2 and LE3, and is also formed on the second transparent layer TL12 immediately above each upper portion 62. Moreover, the sealing layer SE1 is in contact with the lower portion 61 of the partition 6. In the sealing layer SE1, the portion which is formed immediately above each upper portion 62 is continuous with the portion which is formed immediately above each of the lower electrodes. The sealing layer SE1 is formed of silicon nitride by a CVD method.

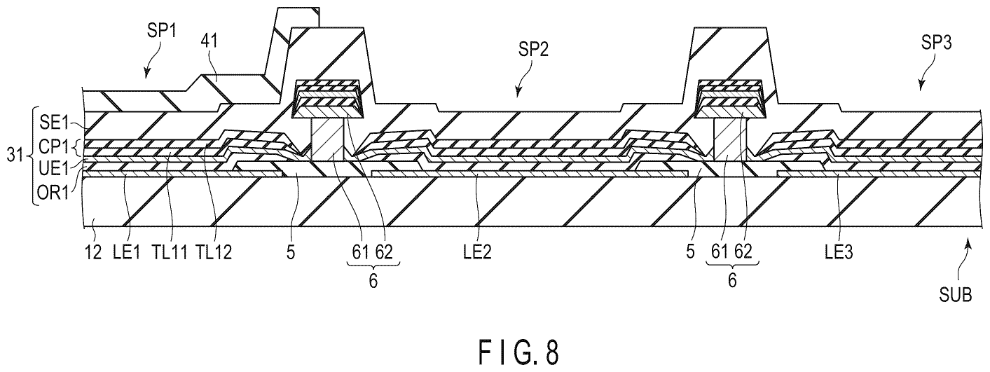

Subsequently, in step ST22, as shown in FIG. 8, the patterned first resist 41 is formed on the sealing layer SE1. The first resist 41 covers the first thin film 31 of subpixel SP1, and the first thin film 31 is exposed from the first resist 41 in subpixels SP2 and SP3. Thus, the first resist 41 overlaps the sealing layer SE1 located immediately above the lower electrode LE1. The first resist 41 extends from subpixel SP1 to the upper side of the partition 6. Immediately above the partition 6 between subpixel SP1 and subpixel SP2, the first resist 41 is provided on the subpixel SP1 side (the left side of the figure), and the sealing layer SE1 is exposed from the first resist 41 on the subpixel SP2 side (the right side of the figure). The sealing layer SE1 is exposed from the first resist 41 in subpixel SP2 and subpixel SP3.

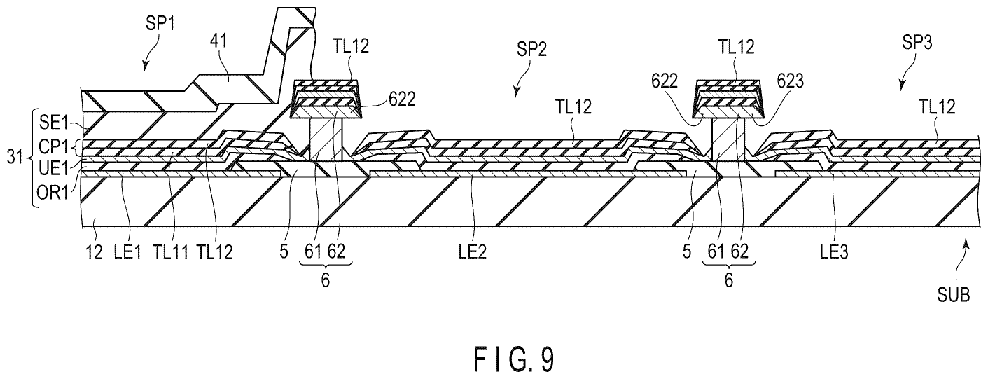

Subsequently, in step ST23, as shown in FIG. 9 to FIG. 11, etching is applied using the first resist 41 as a mask. By this process, the first thin film 31 exposed from the first resist 41 in subpixels SP2 and SP3 is removed, and the first thin film 31 remains in subpixel SP1.

The process of removing the first thin film 31 is, for example, as follows.

First, as shown in FIG. 9, dry etching is performed using the first resist 41 as a mask to remove the sealing layer SE1 exposed from the first resist 41. By this process, of the cap layer CP1, part of the second transparent layer TL12 is exposed from the sealing layer SE1.

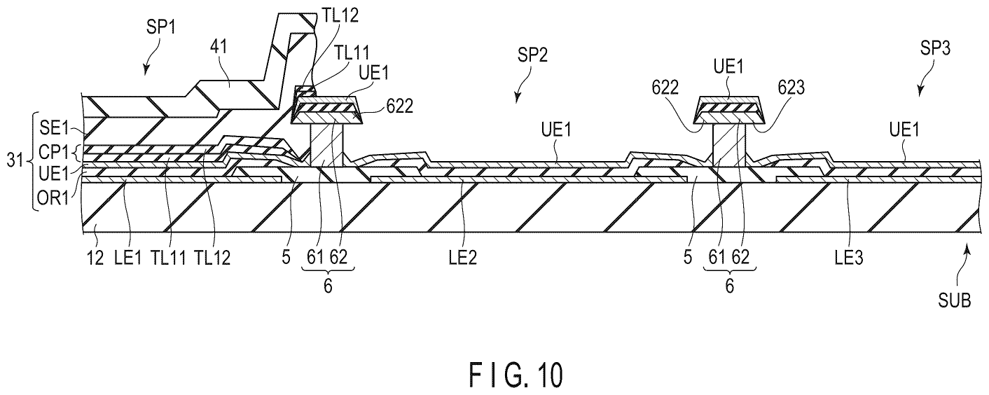

Subsequently, as shown in FIG. 10, ashing (dry etching for emitting oxygen plasma) is performed using the first resist 41 as a mask to remove the second transparent layer TL12 exposed from the sealing layer SE1.

Subsequently, ashing is performed using the first resist 41 as a mask to remove the first transparent layer TL11 exposed from the second transparent layer TL12. By this process, part of the upper electrode UE1 is exposed from the cap layer CP1.

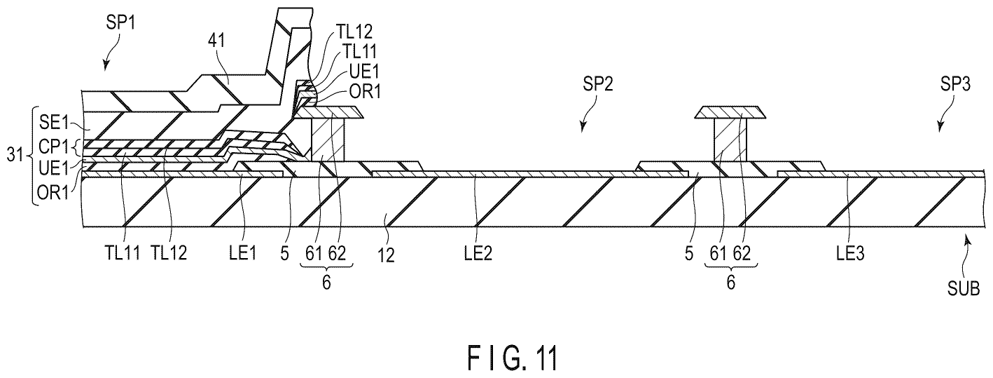

Subsequently, as shown in FIG. 11, wet etching is performed using the first resist 41 as a mask to remove the upper electrode UE1 exposed from the first transparent layer TL11.

Subsequently, ashing is performed using the first resist 41 as a mask to remove the organic layer OR1 exposed from the upper electrode UE1.

In this manner, the lower electrode LE2 is exposed in subpixel SP2, and the rib 5 surrounding the lower electrode LE2 is exposed. In subpixel SP3, the lower electrode LE3 is exposed, and the rib 5 surrounding the lower electrode LE3 is exposed. On the partition 6 between subpixel SP1 and subpixel SP2, the subpixel SP2 side is exposed. Further, the partition 6 between subpixel SP2 and subpixel SP3 is exposed.

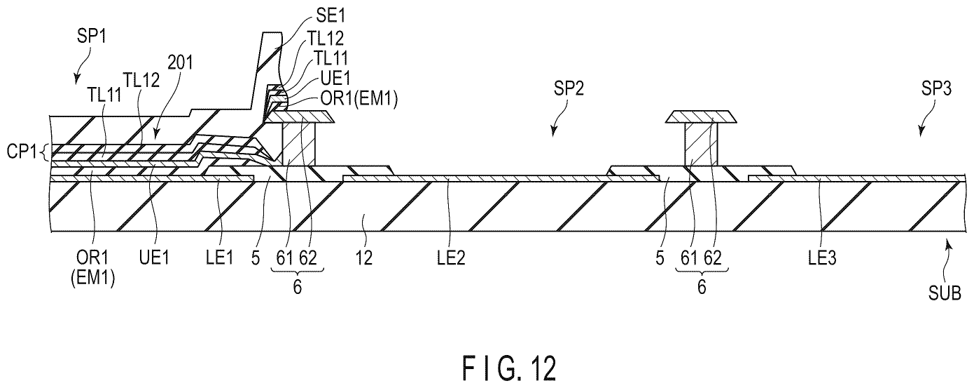

Subsequently, in step ST24, as shown in FIG. 12, the first resist 41 is removed. Thus, the sealing layer SE1 of subpixel SP1 is exposed. Through these steps ST21 to ST24, the display element 201 is formed in subpixel SP1. The display element 201 consists of the lower electrode LE1, the organic layer OR1 including the light emitting layer EM1, the upper electrode UE1, the first transparent layer TL11 and the second transparent layer TL12. The display element 201 is covered with the sealing layer SE1.

A stacked layer body of the organic layer OR1 including the light emitting layer EM1, the upper electrode UE1, the first transparent layer TL11, the second transparent layer TL12 and the sealing layer SE1 is formed on the partition 6 between subpixel SP1 and subpixel SP2. The stacked layer body located on the partition 6 is spaced apart from the organic layer OR1, the upper electrode UE1, the first transparent layer TL11, the second transparent layer TL12 and the sealing layer SE1 constituting the display element 201. Of the partition 6, the portion on the subpixel SP1 side is covered with the sealing layer SE1. It should be noted that the stacked layer body on the partition 6 shown in FIG. 12 is completely eliminated in some cases.

Steps ST31 to ST34 shown in FIG. 5 are similar to steps ST21 to ST24 described above. Through these steps ST31 to ST34, the display element 202 is formed in subpixel SP2 shown in FIG. 3. The display element 202 consists of the lower electrode LE2, the organic layer OR2 including the light emitting layer EM2, the upper electrode UE2, the first transparent layer TL21 and the second transparent layer TL22. The display element 202 is covered with the sealing layer SE2.

Steps ST41 to ST44 shown in FIG. 5 are also similar to steps ST21 to ST24 described above. Through these steps ST41 to ST44, the display element 203 is formed in subpixel SP3 shown in FIG. 3. The display element 203 consists of the lower electrode LE3, the organic layer OR3 including the light emitting layer EM3, the upper electrode UE3, the first transparent layer TL31 and the second transparent layer TL32. The display element 203 is covered with the sealing layer SE3.

In the present embodiment, the display elements 201 to 203 comprise the cap layers CP1 to CP3, respectively, which function as optical adjustment layers. Thus, the light emitted from the light emitting layers EM1 to EM3 is reflected on the interfaces between the first and second transparent layers constituting the cap layers CP1 to CP3, respectively, and is reflected on the upper electrodes again. By the microcavity effect using such interference of reflected light, the light extraction efficiency for each display element can be improved.

Now, the manufacturing device of the display device DSP is explained. Here, for example, this specification explains a manufacturing device 100 for forming the organic layer OR1, upper electrode UE1 and cap layer CP1 of the display element 201. It should be noted that a manufacturing device for forming the organic layer OR2, upper electrode UE2 and cap layer CP2 of the display element 202 and a manufacturing device for forming the organic layer OR3, upper electrode UE3 and cap layer CP3 of the display element 203 can be configured in the same manner as the manufacturing device 100 explained here.

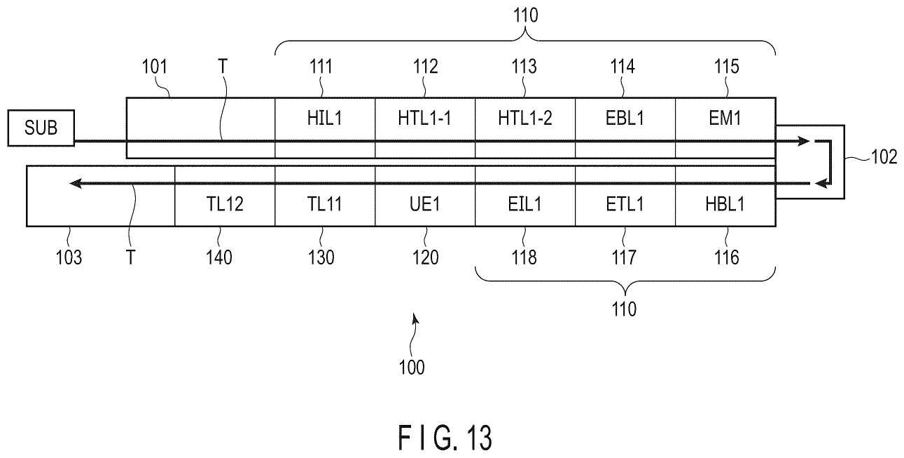

FIG. 13 is a diagram for explaining a configuration example of the manufacturing device 100.

The manufacturing device 100 is applied to the process of forming the organic layer OR1, the upper electrode UE1 and the cap layer CP1 in the process of forming the first thin film 31 explained with reference to FIG. 5 and FIG. 7. It is assumed that the configuration of the display element 201 is the single configuration shown in FIG. 4.

The manufacturing device 100 comprises a preprocessing portion 101, a direction conversion portion 102, a post-processing portion 103, a first evaporation portion 110, a second evaporation portion 120, a third evaporation portion 130, a fourth evaporation portion 140, and a conveyance mechanism which conveys the processing substrate SUB along a conveyance path T. In the manufacturing device 100, at least the first evaporation portion 110 to the fourth evaporation portion 140 are maintained in a predetermined reduced-pressure state.

For example, the preprocessing portion 101 comprises a processing substrate formation portion which forms the processing substrate SUB comprising the lower electrodes, rib, partition, etc., explained in step ST1, and a processing portion which performs various processes for the processing substrate SUB such as a cleaning process, a drying process and a plasma process. The preprocessing portion 101 comprises a mechanism which sets the processing substrate SUB so as to be in a predetermined conveyance posture, a mechanism which secures the processing substrate SUB to a dedicated carrier by an electrostatic chuck, etc. The carrier is conveyed along the conveyance path T by the conveyance mechanism.

The post-processing portion 103 comprises a mechanism which releases the securing applied by the electrostatic chuck and removes the processing substrate SUB from the carrier, a mechanism which sets the processing substrate SUB so as to be in a predetermined posture, etc.

The first evaporation portion 110 is configured to form the organic layer OR1 shown in FIG. 4 and comprises a plurality of evaporation portions. In the example shown in the figure, the first evaporation portion 110 comprises eight evaporation portions 111 to 118. However, the first evaporation portion 110 may comprise more evaporation portions.

The evaporation portions 111 to 115 are arranged in line along the conveyance path T and are connected to each other. The evaporation portions 116 to 118 are arranged in line along the conveyance path T and are connected to each other. The evaporation portion 115 and the evaporation portion 116 are connected to the direction conversion portion 102. In the example shown in the figure, the direction conversion portion 102 is configured to convert the conveyance direction of the processing substrate SUB 180°.

The evaporation portion 111 connected to the preprocessing portion 101 is configured to form the hole injection layer HIL1 on the lower electrode LE1.

The evaporation portion 112 connected to the evaporation portion 111 is configured to form a first thin film HTL1-1 constituting the hole transport layer HTL1 on the hole injection layer HIL1.

The evaporation portion 113 connected to the evaporation portion 112 is configured to form a second thin film HTL1-2 constituting the hole transport layer HTL1 on the first thin film HTL1-1.

The evaporation portion 114 connected to the evaporation portion 113 is configured to form the electron blocking layer EBL1 on the second thin film HTL1-2.

The evaporation portion 115 connected to the evaporation portion 114 is configured to form the light emitting layer EM1 on the electron blocking layer EBL1. Further, the evaporation portion 115 is connected to the direction conversion portion 102.

The evaporation portion 116 connected to the direction conversion portion 102 is configured to form the hole blocking layer HBL1 on the light emitting layer EM1.

The evaporation portion 117 connected to the evaporation portion 116 is configured to form the electron transport layer ETL1 on the hole blocking layer HBL1.

The evaporation portion 118 connected to the evaporation portion 117 is configured to form the electron injection layer EIL1 on the electron transport layer ETL1.

The second evaporation portion 120 connected to the evaporation portion 118 is configured to form the upper electrode UE1 on the electron injection layer EIL1.

The third evaporation portion 130 connected to the second evaporation portion 120 is configured to deposit the first organic material on the upper electrode UE1 and form the first transparent layer TL11.

The fourth evaporation portion 140 connected to the third evaporation portion 130 is configured to deposit the second organic material on the first transparent layer TL11 and form the second transparent layer TL12. Further, the fourth evaporation portion 140 is connected to the post-processing portion 103.

This specification hereinafter explains the manufacturing process in the manufacturing device 100.

The processing substrate SUB which has been carried into the manufacturing device 100 is conveyed along the conveyance path T and is firstly carried into the preprocessing portion 101. In the preprocessing portion 101, a predetermined preprocess is performed for the processing substrate SUB.

Subsequently, the processing substrate SUB is carried into the evaporation portion 111. In the evaporation portion 111, an organic material for forming the hole injection layer HIL1 is deposited on the processing substrate SUB.

Subsequently, the processing substrate SUB is carried into the evaporation portion 112. In the evaporation portion 112, an organic material for forming the first thin film HTL1-1 of the hole transport layer is deposited on the processing substrate SUB.

Subsequently, the processing substrate SUB is carried into the evaporation portion 113. In the evaporation portion 113, an organic material for forming the second thin film HTL1-2 of the hole transport layer is deposited on the processing substrate SUB.

Subsequently, the processing substrate SUB is carried into the evaporation portion 114. In the evaporation portion 114, an organic material for forming the electron blocking layer EBL1 is deposited on the processing substrate SUB.

Subsequently, the processing substrate SUB is carried into the evaporation portion 115. In the evaporation portion 115, an organic material for forming the light emitting layer EM1 is deposited on the processing substrate SUB.

Subsequently, the processing substrate SUB is carried into the evaporation portion 116 via the direction conversion portion 102. In the evaporation portion 116, an organic material for forming the hole blocking layer HBL1 is deposited on the processing substrate SUB.

Subsequently, the processing substrate SUB is carried into the evaporation portion 117. In the evaporation portion 117, an organic material for forming the electron transport layer ETL1 is deposited on the processing substrate SUB.

In the evaporation portions 111 to 117, organic materials different from each other are deposited on the processing substrate SUB.

Subsequently, the processing substrate SUB is carried into the evaporation portion 118. In the evaporation portion 118, an inorganic material for forming the electron injection layer EIL1 is deposited on the processing substrate SUB.

Subsequently, the processing substrate SUB is carried into the second evaporation portion 120. In the second evaporation portion 120, an inorganic material for forming the upper electrode UE1 is deposited on the processing substrate SUB.

In the evaporation portion 118 and the second evaporation portion 120, inorganic materials different from each other are deposited on the processing substrate SUB.

Subsequently, the processing substrate SUB is carried into the third evaporation portion 130. In the third evaporation portion 130, the first organic material for forming the first transparent layer TL11 is deposited on the processing substrate SUB.

Subsequently, the processing substrate SUB is carried into the fourth evaporation portion 140. In the fourth evaporation portion 140, the second organic material for forming the second transparent layer TL12 is deposited on the processing substrate SUB.

In the third evaporation portion 130 and the fourth evaporation portion 140, organic materials different from each other are deposited on the processing substrate SUB.

Subsequently, the processing substrate SUB is carried into the post-processing portion 103. In the post-processing portion 103, a predetermined post-process is performed for the processing substrate SUB. Subsequently, the processing substrate SUB is carried out of the manufacturing device 100.

Now, this specification explains the typical configuration of an evaporation portion.

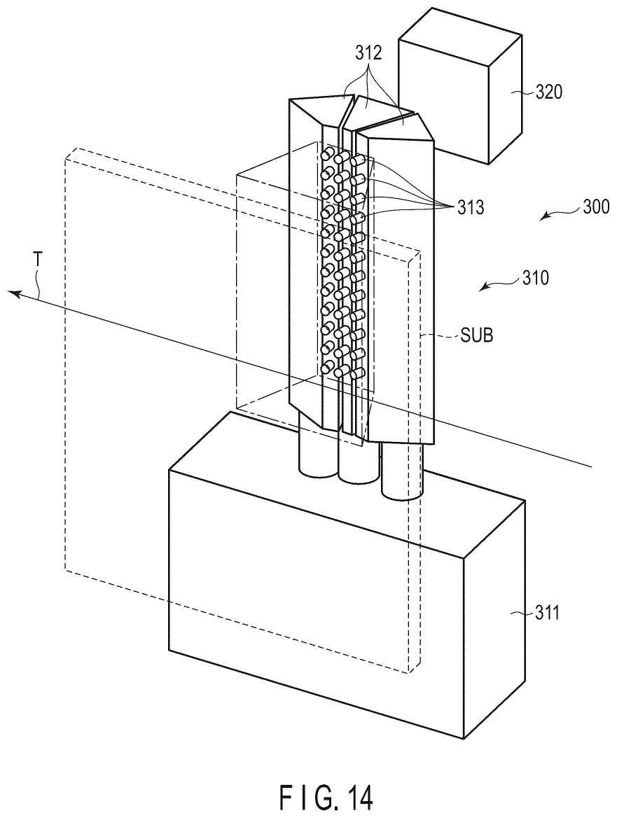

FIG. 14 is a perspective view schematically showing the main part of an evaporation portion 300.

The evaporation portion 300 comprises an evaporation source 310 and a film thickness measurement device 320.

The evaporation source 310 comprises a crucible 311 which heats materials, a plurality of evaporation heads 312 connected to the crucible 311, and first and second nozzles 313 and 314 (314 not shown in FIG. 14) which emit the material evaporated from each of the evaporation heads 312. The first nozzles 313 are arranged in a direction orthogonal to the conveyance path T of the processing substrate SUB.

The film thickness measurement device 320 faces the evaporation source 310. The conveyance path T is provided on the opposite side of the film thickness measurement device 320 across the intervening evaporation source 310.

The configuration of the evaporation portion 300 shown in FIG. 14 can be applied to each of the evaporation portions shown in FIG. 13.

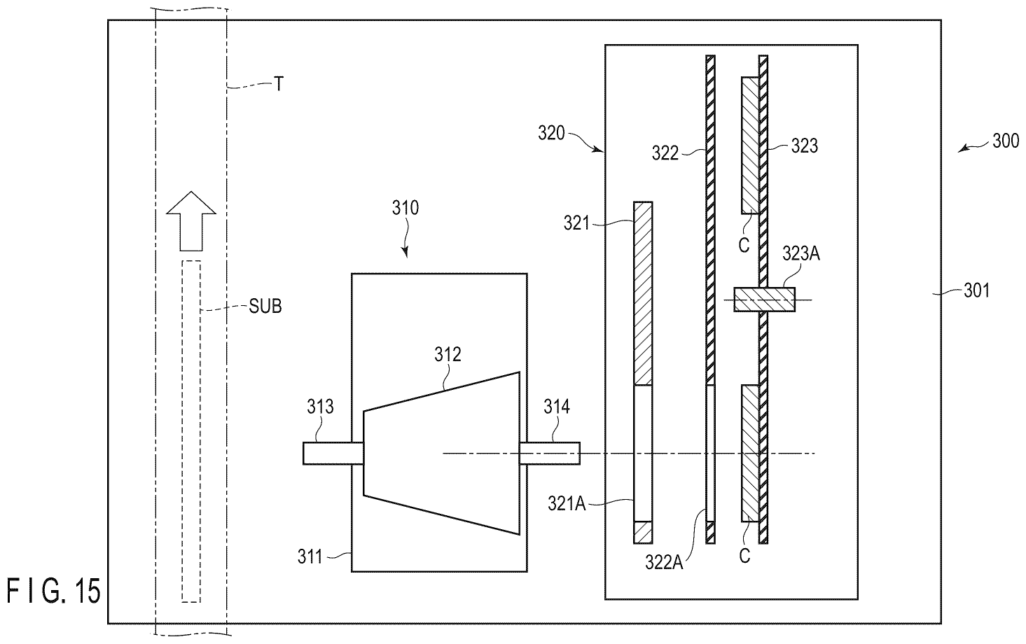

FIG. 15 is a top view schematically showing the main part of the evaporation portion 300. Here, the figure shows one of the evaporation heads 312.

The evaporation source 310 and the film thickness measurement device 320 are accommodated in a chamber 301. The first nozzle 313 faces the processing substrate SUB shown by dashed lines or the conveyance path T shown by two-dot chain lines. The second nozzle 314 faces the film thickness measurement device 320. In other words, the nozzle which emits a material to the processing substrate SUB is a different piece from the nozzle which emits a material to the film thickness measurement device 320.

The film thickness measurement device 320 comprises a shutter 321 comprising an aperture 321A, a cover 322 comprising an aperture 322A, a holder 323 configured to rotate around a rotation axis 323A, and a plurality of crystal oscillators C provided on the same surface of the holder 323. The cover 322 is located between the shutter 321 and the crystal oscillators C. When the material emitted from the second nozzle 314 is deposited on a crystal oscillator C, the shutter 321 is driven such that the aperture 321A is located on the same axis as the aperture 322A.

Each crystal oscillator C comprises, for example, a structure in which a crystal plate is held between a pair of metal electrodes. When the material emitted from the second nozzle 314 is deposited on the metal electrode, the frequency of the crystal oscillator C is changed. The frequency of the crystal oscillator C attenuates in connection with the attachment of the material. Thus, in the film thickness measurement device 320, the evaporation rate of the material is measured based on the frequency of each crystal oscillator C, and further, the thickness of the thin film formed on each crystal oscillator C and the thickness of the thin film formed on the processing substrate SUB are measured.

For example, when the evaporation portion 300 shown in the figure corresponds to the fourth evaporation portion 140 shown in FIG. 13, the evaporation source 310 heats the second organic material accommodated in the crucible 311 and emits the evaporated second organic material from the first nozzle 313 and the second nozzle 314. The second organic material emitted from the second nozzle 314 is deposited on at least one of the crystal oscillators C via the aperture 321A and the aperture 322A. The film thickness measurement device 320 can measure the evaporation rate of the second organic material, the thickness of the second organic material deposited on the crystal oscillator C and the thickness of the second organic material deposited on the processing substrate SUB based on the frequency of the crystal oscillator C.

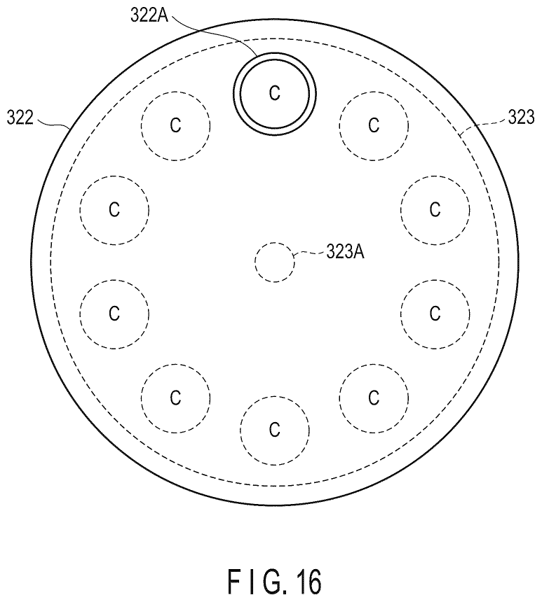

FIG. 16 is a front view of the cover 322 and the holder 323.

The holder 323 is formed into the shape of a circular disk. The crystal oscillators C are arranged at intervals in the circumferential direction of the holder 323. In the example shown in the figure, 10 crystal oscillators C are provided in the holder 323. It should be noted that the number of crystal oscillators C provided in the holder 323 is not limited to the example shown in the figure.

The cover 322 is formed so as to cover the holder 323 and the crystal oscillators C. The aperture 322A of the cover 322 is formed so as to face one crystal oscillator C. It should be noted that the aperture 322A may be formed so as to face a plurality of crystal oscillators C.

The material emitted from the evaporation source is deposited on the crystal oscillator C facing the aperture 322A. After the deposited material reaches a predetermined thickness or after a predetermined evaporation rate is reached, the holder 323 rotates around the rotation axis 323A, and another crystal oscillator C faces the second nozzle 314 via the aperture 322A.

To accurately obtain the thickness of the thin film formed on the processing substrate SUB by the method described above, the vapor deposition relative to the processing substrate SUB and the vapor deposition relative to the crystal oscillator C are required to start at the same time and equally proceed. However, some of the materials of the thin films formed on the processing substrate SUB are not easily deposited on unused crystal oscillators C. For example, it is difficult to form a thin film on the crystal oscillators C by the second organic material which forms the second transparent layer TL12 described above. Therefore, the thickness of the second organic material may not be accurately measured.

In this respect, in the present embodiment, in the fourth evaporation portion 140, before the vapor deposition of the second organic material relative to the processing substrate SUB is started, the second organic material is emitted from the first and second nozzles 313 and 314 of the evaporation source 310 to deposit the second organic material on all of the crystal oscillators C on the holder 323 in advance. This process is called a pre-deposition process.

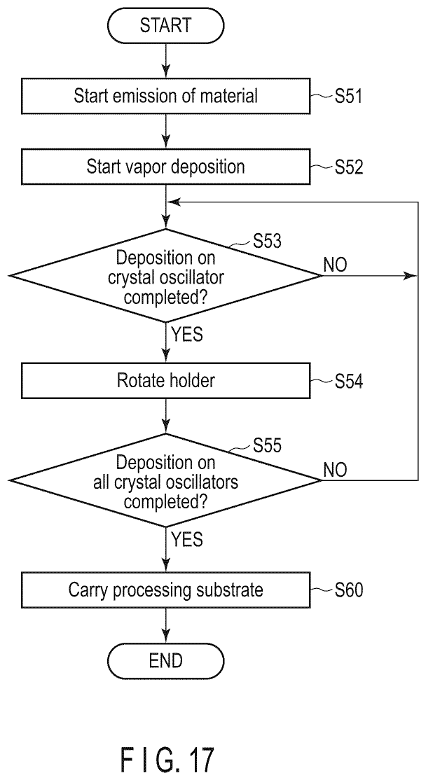

FIG. 17 is a flowchart for explaining a pre-deposition process. The pre-deposition process explained here is performed before the second transparent layer TL12 is formed in the processing substrate SUB in which the first transparent layer TL11 is formed, in other words, before the processing substrate SUB is carried into the fourth evaporation portion 140. This pre-deposition process should be preferably performed before the organic layer OR1 is formed in the processing substrate SUB, in other words, before the processing substrate SUB is carried into the first evaporation portion 110.

First, the second organic material accommodated in the crucible 311 is heated. By this process, the emission of the second organic material from the first nozzle 313 and the second nozzle 314 is started (step S51).

Subsequently, the shutter 321 is driven such that the aperture 321A is provided on the same axes of the second nozzle 314 and the aperture 322A of the cover 322. By this process, at least one crystal oscillator C faces the second nozzle 314, and the vapor deposition of the second organic material relative to the crystal oscillator C is started (step S52). As the vapor deposition of the second organic material relative to the crystal oscillator C proceeds, an underlying film is formed on the crystal oscillator C.

Subsequently, whether or not the vapor deposition of the second organic material relative to the crystal oscillator C is completed (in other words, whether or not an underlying film having a predetermined thickness is formed on the crystal oscillator C) is determined based on the frequency of the crystal oscillator C facing the second nozzle 314 (step S53). For example, when the difference between the evaporation rate measured based on the frequency of the crystal oscillator C and the set evaporation rate is within ±2%, and this evaporation rate continues for more than 10 minutes, it is possible to determine that the vapor deposition of the second organic material is competed. Alternatively, when a predetermined time elapsed from the start of the vapor deposition relative to the crystal oscillator C, it is possible to determine that the vapor deposition of the second organic material is completed. Alternatively, when the frequency of the crystal oscillator C reaches a predetermined frequency, it is possible to determine that the vapor deposition of the second organic material is completed.

When the vapor deposition of the second organic material is completed as a result of determination (YES in step S53), the holder 323 rotates, and another crystal oscillator C faces the second nozzle 314, and the vapor deposition of the second organic material relative to this crystal oscillator C is started (step S54).

These steps S52 to S54 are repeated until the vapor deposition of the second organic material relative to all of the crystal oscillators C located on the holder 323 is completed.

When the vapor deposition of the second organic material relative to all of the crystal oscillators C is completed (YES in step S55), the pre-deposition process is terminated. Subsequently, the conveyance of the processing substrate SUB along the conveyance path T is started (step S60).

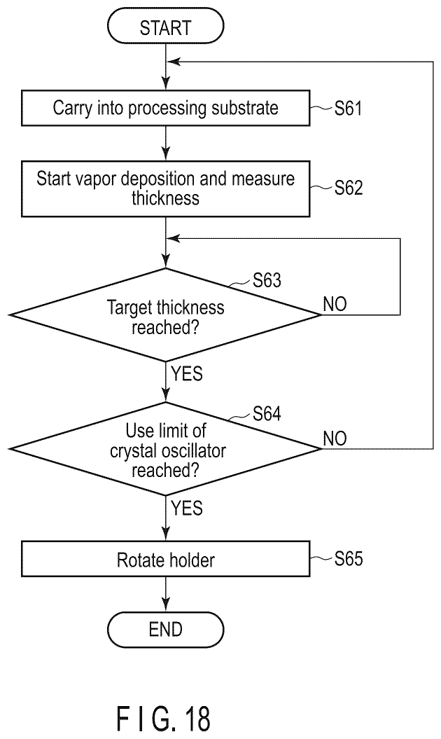

FIG. 18 is a flowchart for explaining the deposition process of a material relative to the processing substrate SUB. The deposition process explained here is performed after the conveyance of the processing substrate SUB of step S60 shown in FIG. 17 is started. It should be noted that a crystal oscillator C which does not reach the use limit is set so as to overlap the aperture 321A and the aperture 322A before the deposition process explained here is started.

Firstly, the processing substrate SUB in which the first transparent layer TL11 is formed is carried into the fourth evaporation portion 140 and is conveyed at a constant speed along the conveyance path T (step S61).

Subsequently, the processing substrate SUB is conveyed so as to face the first nozzles 313 which emit the second organic material. By this configuration, the second organic material emitted from the first nozzles 313 is deposited on the processing substrate SUB.

The second organic material emitted from the second nozzle 314 is deposited on the crystal oscillator C via the aperture 321A and the aperture 322A in the film thickness measurement device 320. The film thickness measurement device 320 measures the evaporation rate and the thickness of the second organic material deposited on the processing substrate SUB based on the frequency of the crystal oscillator C (step S62). The heating temperature of the crucible 311 and the conveyance speed of the processing substrate SUB are controlled based on the evaporation rate measured in the film thickness measurement device 320.

Subsequently, when the attainment of the target thickness of the second organic material is confirmed (YES in step S63), the processing substrate SUB is carried out of the evaporation portion 140.

Subsequently, whether or not the use limit of the crystal oscillator C is reached is determined based on the frequency of the crystal oscillator C (step S64). As described above, the frequency of the crystal oscillator C attenuates in connection with the attachment of the material to the crystal oscillator C. When a large amount of material is attached to the crystal oscillator C, the attenuation rate of the frequency cannot be accurately detected, and the thickness of the deposited material cannot be accurately detected. For this reason, an upper limit is set for the thickness of the material attached to the crystal oscillator C in a range which can accurately detect the thickness. In other words, when the thickness of the material attached to the crystal oscillator C reaches the upper limit, it is possible to determine that the use limit of the crystal oscillator C is reached. It should be noted that upper limits may be set for the number of processing substrates SUB which are carried into the fourth evaporation portion 140 (the number of times in which the crystal oscillator C is used), the elapsed time of the deposition process (the length of time in which the crystal oscillator C is used), etc. When these upper limits are reached, it is possible to determine that the use limit of the crystal oscillator C is reached.

When the crystal oscillator C reaches the use limit as a result of determination (YES in step S64), the holder 323 rotates, and another crystal oscillator C is set so as to overlap the aperture 321A and the aperture 322A (step S65).

In this manner, according to the present embodiment, in each evaporation portion which deposits a material, the evaporation rate is monitored by the film thickness measurement device 320 comprising the crystal oscillators C to control the heating temperature, etc., of the material so as to maintain a constant evaporation rate.

In the fourth evaporation portion 140 which deposits the second organic material which is not easily deposited on unused crystal oscillators C, before the vapor deposition relative to the processing substrate SUB is started, a pre-deposition process which deposits the second organic material on all of the crystal oscillators C is performed in advance. Thus, all of the crystal oscillators C comprise an underlying film formed of the second organic material. In this manner, the thickness of the second organic material deposited on the processing substrate SUB can be accurately measured.

In a case where the crystal oscillator C used for measurement reaches the use limit, a deposition process can be performed immediately after the crystal oscillator C is changed to another crystal oscillator C comprising an underlying film. In this manner, the reduction of the production efficiency is prevented.

Here, this specification explains the example in which a pre-deposition process is performed in the fourth evaporation portion 140. However, in a manner similar to that of the second organic material, magnesium for forming the upper electrode UE1 is not easily deposited on unused crystal oscillators C. For this reason, similarly, the pre-deposition process described above should be preferably performed in the second evaporation portion 120.

As described above, the present embodiment can provide a manufacturing device of a display device and a manufacturing method of a display device such that the reduction in the production efficiency can be prevented.

All of the manufacturing devices and manufacturing methods that can be implemented by a person of ordinary skill in the art through arbitrary design changes to the manufacturing device and manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing method of a display device, comprising:
preparing a processing substrate by forming a lower electrode above a substrate, forming a rib comprising an aperture which overlaps the lower electrode, and forming a partition including a lower portion located on the rib and an upper portion located on the lower portion and protruding from a side surface of the lower portion;
forming an organic layer on the lower electrode in the aperture;
forming an upper electrode on the organic layer;
forming a first transparent layer on the upper electrode by depositing a first organic material on the processing substrate in which the upper electrode is formed;
forming a second transparent layer on the first transparent layer by depositing a second organic material having a refractive index lower than a refractive index of the first organic material on the processing substrate in which the first transparent layer is formed; and
depositing the second organic material on each of a plurality of crystal oscillators included in a film thickness measurement device facing the second nozzle by emitting the second organic material from first and second nozzles of an evaporation source before forming the second transparent layer.

2. The manufacturing method of claim 1, wherein
the second organic material is at least one of polytetrafluoroethylene (PTFE), polyvinylidene fluoride (PVDF) and 2-(perfluorohexyl)ethyl acrylate.

3. The manufacturing method of claim 1, wherein
the processing substrate in which the first transparent layer is formed is conveyed along a conveyance path located on an opposite side of the film thickness measurement device across the intervening evaporation source after the second organic material is deposited on all of the crystal oscillators.

4. The manufacturing method of claim 3, wherein
the processing substrate is conveyed so as to face the first nozzle in a state where at least one of the crystal oscillators faces the second nozzle, and a thickness of the second organic material deposited on the processing substrate is measured based on a frequency of the crystal oscillator facing the second nozzle.

5. The manufacturing method of claim 1, wherein
the crystal oscillators are arranged in a circumferential direction on a holder formed into a shape of a circular disk, and
after the second organic material deposited on the crystal oscillator facing the second nozzle reaches a predetermined thickness, the holder rotates, and another one of the crystal oscillators faces the second nozzle.

6. The manufacturing method of claim 1, wherein
the organic layer, the upper electrode, the first transparent layer and the second transparent layer formed immediately above the upper portion of the partition are spaced apart from the organic layer, the upper electrode, the first transparent layer and the second transparent layer formed immediately above the lower electrode in the aperture.

7. The manufacturing method of claim 6, further comprising
forming a sealing layer using an inorganic material having a refractive index higher than a refractive index of the second transparent layer after the second transparent layer is formed, wherein
the sealing layer covers the second transparent layer on the partition, covers the second transparent layer immediately above the lower electrode and is in contact with the partition.

8. The manufacturing method of claim 7, further comprising:
forming a patterned resist on the sealing layer after the sealing layer is formed; and
removing the sealing layer, the second transparent layer, the first transparent layer, the upper electrode and the organic layer exposed from the resist in series by etching.

9. The manufacturing method of claim 1, wherein
the forming the organic layer includes:
forming a hole injection layer on the lower electrode;
forming a hole transport layer on the hole injection layer;
forming an electron blocking layer on the hole transport layer;
forming a light emitting layer on the electron blocking layer;
forming a hole blocking layer on the light emitting layer;
forming an electron transport layer on the hole blocking layer; and
forming an electron injection layer on the electron transport layer, and
the upper electrode is formed on the electron injection layer.

10. A manufacturing device of a display device, the manufacturing device comprising:
a first evaporation portion which forms, while conveying a processing substrate comprising a lower electrode located above a substrate, a rib comprising an aperture overlapping the lower electrode, and a partition including a lower portion located on the rib and an upper portion located on the lower portion and protruding from a side surface of the lower portion, an organic layer on the lower electrode in the aperture;
a second evaporation portion which forms an upper electrode on the organic layer;
a third evaporation portion which forms a first transparent layer by depositing a first organic material on the upper electrode; and
a fourth evaporation portion which forms a second transparent layer by depositing a second organic material having a refractive index lower than a refractive index of the first organic material on the first transparent layer, wherein
the fourth evaporation portion comprises:
an evaporation source comprising first and second nozzles which emit the second organic material; and
a film thickness measurement device including a plurality of crystal oscillators,
the first nozzle faces a conveyance path of the processing substrate in which the first transparent layer is formed,
the second nozzle faces the film thickness measurement device, and
the fourth evaporation portion is configured to emit the second organic material from the first nozzle and the second nozzle before the second transparent layer is formed, deposit the second organic material on each of the crystal oscillators, and convey the processing substrate along the conveyance path after the second organic material is deposited on all of the crystal oscillators.

11. The manufacturing device of claim 10, wherein
the second organic material is at least one of polytetrafluoroethylene (PTFE), polyvinylidene fluoride (PVDF) and 2-(perfluorohexyl)ethyl acrylate.

12. The manufacturing device of claim 10, wherein
the conveyance path of the processing substrate is provided on an opposite side of the film thickness measurement device across the intervening evaporation source.

13. The manufacturing device of claim 10, wherein
the film thickness measurement device is configured to measure a thickness of the second organic material deposited on the processing substrate based on a frequency of the crystal oscillator facing the second nozzle.

14. The manufacturing device of claim 10, wherein
the crystal oscillators are arranged in a circumferential direction on a holder formed into a shape of a circular disk, and
the holder is configured to rotate after the second organic material deposited on the crystal oscillator facing the second nozzle reaches a predetermined thickness, and another one of the crystal oscillators faces the second nozzle.

15. The manufacturing device of claim 10, wherein
the first evaporation portion comprises:
an evaporation portion which forms a hole injection layer on the lower electrode;
an evaporation portion which forms a hole transport layer on the hole injection layer;
an evaporation portion which forms an electron blocking layer on the hole transport layer;
an evaporation portion which forms a light emitting layer on the electron blocking layer;
an evaporation portion which forms a hole blocking layer on the light emitting layer;
an evaporation portion which forms an electron transport layer on the hole blocking layer; and
an evaporation portion which forms an electron injection layer on the electron transport layer, and
the second evaporation portion is configured to form the upper electrode on the electron injection layer.
